(19) United States
(12) Patent Application Publication
(10) Pub. No.: US 2025/0183008 A1
(43) Pub. Date: Jun. 5, 2025

(54) SHOWER HEAD ASSEMBLY AND PLASMA PROCESSING APPARATUS INCLUDING THE SAME

(71) Applicant: SEMES CO., LTD., Cheonan-si (KR)

(72) Inventors: Sung Yeon KIM, Cheonan-si (KR); Ho Ik KIM, Cheonan-si (KR)

(73) Assignee: SEMES CO., LTD., Cheonan-si (KR)

(21) Appl. No.: 18/962,260

(22) Filed: Nov. 27, 2024

(30) Foreign Application Priority Data
Dec. 1, 2023 (KR) 10-2023-0172634

(51) Int. Cl. H01J 37/32; B05B 1/00; B05B 15/65

(52) U.S. Cl. CPC H01J 37/3244; B05B 1/005; B05B 15/65

(57) ABSTRACT

Proposed is a plasma processing apparatus including a shower head assembly which is easy to be replaced. The shower head assembly which is configured to spray a processing gas into a processing space of a chamber in which a substrate is processed in the plasma processing apparatus includes an upper plate securely installed in an upper space of the chamber, a gas distribution plate arranged at a lower portion of the upper plate and having multiple through holes, a shower plate arranged at a lower portion of the gas distribution plate and having gas spraying holes connected to the through holes, and a fastener configured to fasten the gas distribution plate and the shower plate.

### CROSS REFERENCE TO RELATED APPLICATIONS

The present application claims priority to Korean Patent Application No. 10-2023-0172634, filed Dec. 1, 2023, the entire contents of which is incorporated herein for all purposes by this reference.

### BACKGROUND

### Technical Field

The present disclosure relates to a shower head assembly and a plasma processing apparatus including the same. More particularly, the present disclosure relates to a shower head assembly configured to spray processing gas into a processing space of a chamber where a substrate is processed, and a plasma processing apparatus including the same.

### Description of the Related Art

In a manufacturing process of semiconductor devices or liquid crystal displays, a plasma processing apparatus is used to generate plasma in a chamber decompressed to a predetermined vacuum pressure, to apply the plasma to a substrate, for example, a semiconductor wafer or a glass substrate for a liquid crystal display device, etc., and to perform a predetermined processing such as a deposition process, an etching process, and an ashing process.

In general, the plasma processing apparatus processing a substrate by using plasma includes a shower head assembly. The shower head assembly may be supplied with gas required for a process and spray the gas evenly into a processing space in the chamber.

FIG. 1 is a view simply illustrating an existing shower head assembly 40. Referring to FIG. 1, the existing shower head assembly 40 may include an upper plate 42, a gas distribution plate 44, and a shower plate 46. The upper plate 42 is coupled to a chamber 100, the gas distribution plate 44 is arranged at a lower portion of the upper plate 42, and the shower plate 46 may be arranged at a lower portion of the gas distribution plate 44. Gas supplied from a gas supply assembly 300 may be supplied to the processing space in the chamber through the shower head assembly 40. In the shower head assembly 40 having the above-described configuration, the upper plate 42, the gas distribution plate 44 and the shower plate 46 may be fastened to each other by a fastening bolt 50. As the process is performed using plasma, the shower plate 46 of the shower head assembly 40 is most exposed to the plasma, which causes degradation and periodic replacement is required.

In order to replace the shower plate 46 in the conventional shower head assembly 40, the shower plate 46 should be replaced after the fastening bolts 50 between the chamber 100 and the upper plate 42 are disassembled and the fastening bolts 50 between the gas distribution plate 44 and the shower plate 46 are disassembled. Therefore, there is a disadvantage in that a replacement time is long.

### SUMMARY

Accordingly, the present disclosure has been made keeping in mind the above problem occurring in the related art, and there is provided a plasma processing apparatus including a shower head assembly which is easy to be replaced.

The objective of the present disclosure is not limited to the above-mentioned objective, and other objectives not mentioned will be clearly understood by those skilled in the art from the subsequent description.

According to the present disclosure, there is provided a shower head assembly configured to spray a processing gas into a processing space of a chamber in which a substrate is processed in a plasma processing apparatus, the shower head assembly including: an upper plate securely installed in an upper space of the chamber; a gas distribution plate arranged at a lower portion of the upper plate and having multiple through holes; a shower plate arranged at a lower portion of the gas distribution plate and having gas spraying holes connected to the through holes; and a fastener configured to fasten the gas distribution plate and the shower plate. The fastener may include: a fixed block securely fastened to the shower plate and inserted into a receiving space formed in the gas distribution plate; a spring inserted into an internal space of the fixed block; a pressure block installed at a lower portion of the spring; a rotation block provided at a lower portion of the pressure block and having an oval section with a pattern hole formed therein; and a key rod inserted into the pattern hole of the rotation block.

According to the embodiment, the fixed block may include: a body part having a first space and a second space formed in a circular shape below the first space, the body part being inserted into the receiving space of the gas distribution plate; and a screw part formed to extend from a lower portion of the body part and coupled to a fastening port formed in the shower plate.

According to the embodiment, the spring may be a coil spring.

According to the embodiment, the pressure block may include: an insertion part provided in contact with the spring; and a pressure part brought into contact with the rotation block and having a semicircular section.

According to the embodiment, the fixed block may have circular opening parts on opposite walls.

According to the embodiment, a pattern hole having a patterned shape may be formed in the rotation block.

According to the embodiment, the key rod may include: a rod part having a section corresponding to the patterned shape; and a nob part formed at an end of the rod part.

According to the present disclosure, there is provided a shower head assembly configured to spray a processing gas into a processing space of a chamber in which a substrate is processed in a plasma processing apparatus, the shower head assembly including: an upper plate securely installed in an upper space of the chamber, a gas distribution plate arranged at a lower portion of the upper plate, having multiple through holes formed in a vertical direction, and having side holes formed in a horizontal direction passing through a central point; a shower plate arranged at a lower portion of the gas distribution plate and having gas spraying holes connected to the through holes; and a fastener configured to fasten the gas distribution plate and the shower plate.

The fastener may include: multiple fixed blocks securely fastened to the shower plate and inserted into multiple receiving spaces formed along the side holes; a spring installed in an internal space of each fixed block; a pressure block installed at a lower portion of the spring; a rotation block provided at a lower portion of the pressure block and having an oval section with a pattern hole formed therein; and a key rod inserted into the pattern hole of the rotation block.

According to the embodiment, the key rod may pass through the opening parts and the pattern hole and be inserted into rotation blocks of the multiple fixed blocks simultaneously to rotate the multiple rotation blocks.

According to the present disclosure, there is provided a plasma processing apparatus including: a chamber providing a processing space for a substrate; a substrate support assembly arranged in the processing space and configured to support the substrate; a gas supply assembly configured to supply gas required for a process to the processing space; and a shower head assembly configured to spray the supplied gas into the processing space.

The shower head assembly may include: an upper plate securely installed in an upper space of the chamber; a gas distribution plate arranged at a lower portion of the upper plate, having multiple through holes formed in a vertical direction, and having side holes formed in a horizontal direction passing through a central point; a shower plate arranged at a lower portion of the gas distribution plate and having gas spraying holes connected to the through holes; and a fastener configured to fasten the gas distribution plate and the shower plate.

The fastener may include: a fixed block securely fastened to the shower plate, inserted into each of multiple receiving spaces formed in the gas distribution plate, and having a first space and a second space extending from a lower portion of the first space and having a circular section; a spring installed at a ceiling of the first space; a pressure block installed in the first space and at a lower portion of the spring; a rotation block provided at a lower portion of the pressure block and having an oval section with a pattern hole formed therein; and a key rod inserted into the pattern hole of the rotation block.

In the fixed block, circular opening parts may be formed on walls of the second space. A pattern hole having a patterned shape may be formed in the rotation block. The key rod may be inserted into the opening parts and the pattern hole to rotate the rotation block, and the key rod may pass through the opening parts and the pattern hole and be inserted into rotation blocks of multiple fixed blocks simultaneously to rotate the multiple rotation blocks.

According to the present disclosure, the gas distribution plate and the shower plate are simply coupled to each other and disassembled from each other, so a replacement time of the shower plate can be reduced.

The effect of the present disclosure is not limited to the above-mentioned description, and other effects not mentioned will be clearly understood by those skilled in the art from the following drawings.

### BRIEF DESCRIPTION OF THE DRAWINGS

FIG. 1 is a sectional view illustrating a structure of an existing shower head assembly.

FIG. 2 is a view illustrating a plasma processing apparatus according to the present disclosure.

FIG. 3 is a sectional view illustrating a structure of the shower head assembly according to the present disclosure.

FIG. 4 is a view illustrating a gas distribution plate.

FIG. 5 is a view illustrating a coupling structure of a shower plate and the gas distribution plate.

FIG. 6 is a view illustrating an inserting structure of a fastener in the gas distribution plate.

FIGS. 7A to 7C are views illustrating a structure of the fastener of the shower head assembly.

FIGS. 8A to 8C are views illustrating a structure of a fixed block.

FIGS. 9A to 9D are views illustrating a spring, a pressure block, a rotation block, and a key rod.

FIGS. 10A to 10C are views illustrating a process in which the gas distribution plate and the shower plate are coupled to each other by the fastener.

FIG. 11 is a view illustrating a process for determining the rotation block and the spring.

FIGS. 12A to 12C are views illustrating modifications of the fastener.

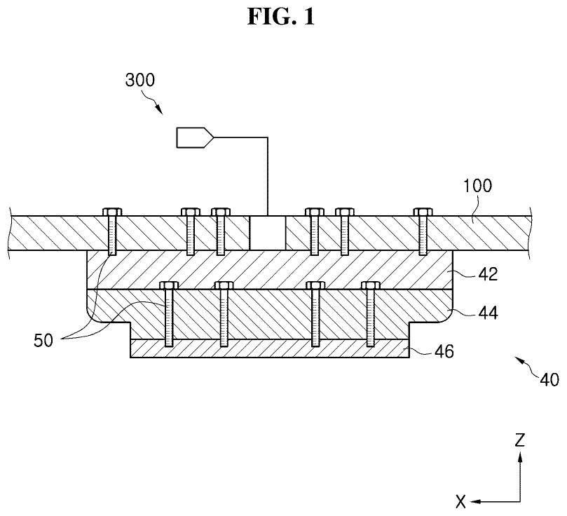

### DETAILED DESCRIPTION

Hereinbelow, embodiments of the present disclosure will be described in detail with reference to the accompanying drawings such that the present disclosure can be easily embodied by one of ordinary skill in the art to which the present disclosure belongs. However, the present disclosure may be implemented in several different forms and is not limited to the embodiments described hereinbelow.

In describing the embodiments of the present disclosure, if it is determined that a specific description of a related known function of configuration may unnecessarily obscure the gist of the present disclosure, specific description is omitted, and parts in which similar functions or operations are performed will use the same reference numerals throughout the drawings.

Furthermore, in various embodiments, elements with the same configuration will be described in a representative embodiment by using the same reference numeral, and different configurations from the representative embodiment will be described in other embodiments.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words, such as “between” versus “directly between”, “adjacent” versus “directly adjacent”, etc., used to describe the relationship between elements should be interpreted in a like fashion. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

In the flowing description, unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The present disclosure relates to a shower head assembly 400 and a plasma processing apparatus 10 including the same. More particularly, the present disclosure relates to a shower head assembly 400 configured to spray a processing gas into a processing space of a chamber 100 in which a substrate W is processed, and a plasma processing apparatus 10 including the same.

The plasma processing apparatus 10 is an apparatus to perform plasma processing (ex., dry etching processing) for the substrate W. When the substrate W is inserted into the plasma processing apparatus 10, high-frequency power is applied to upper and lower electrodes to generate an electromagnetic field, and the processing gas supplied to the substrate W turns into a plasma state by the electromagnetic field and reacts with a specific material of the substrate W. The substrate W plasma-processed for a predetermined time is discharged outward from the plasma processing apparatus 10, and a later process continues.

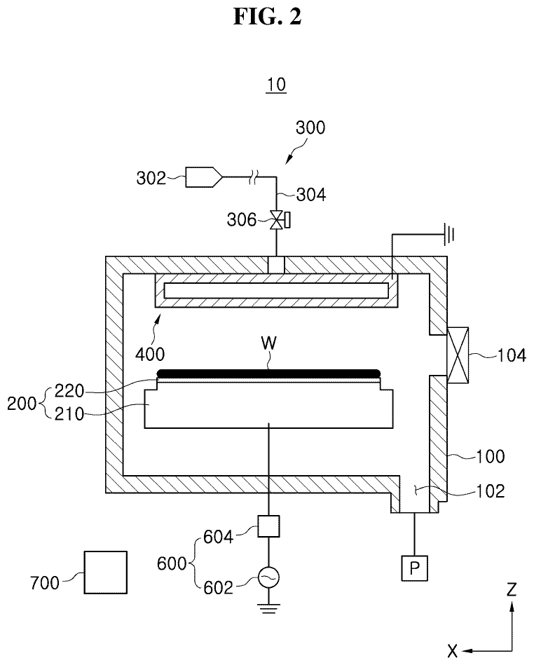

FIG. 2 is a view illustrating the plasma processing apparatus 10 according to the present disclosure. Referring to FIG. 2, the plasma processing apparatus 10 may include the chamber 100, a substrate support assembly 200, a gas supply assembly 300, the shower head assembly 400, a plasma generating device 600, and a controller 700.

The chamber 100 includes a processing space in which a plasma process is performed. The chamber 100 may include an exhaust port 102 at a lower portion thereof, and the exhaust port 102 may be connected to an exhaust line with a pump P mounted thereto. The exhaust port 102 may discharge a reaction byproduct generated in the plasma process and gas remaining in the chamber 100, out of chamber 100 through the exhaust line. In this case, the internal space of the chamber 100 may be decompressed to a predetermined pressure.

The chamber 100 may have an opening part 104 on a lateral wall thereof. The opening part 104 may serve as a passage through which the substrate W is inserted into and removed from the inside space of the chamber 100. The opening part 104 may be configured to be opened and closed by a door assembly.

The substrate support assembly 200 may be arranged at a lower area inside the chamber 100. The substrate support assembly 200 may support the substrate W by an electrostatic force. However, the embodiment is not limited thereto, and the substrate W may be supported by various methods such as mechanical clamping, vacuum, etc.

The substrate support assembly 200 may include a support body 210 and an electrostatic chuck 220 arranged at an upper surface of the support body 210. The electrostatic chuck 220 may be configured to electrostatically adsorb the substrate W and may include a ceramic layer in which an electrode is interposed.

Although not shown in the drawings, a heating member and a cooling member may be provided in the substrate support assembly 200 to maintain the substrate W at a process temperature when performing a process. The heating member may be a heating wire, and the cooling member may be a cooling line in which a refrigerant flows.

The gas supply assembly 300 may supply the gas required for the process into the processing space of the chamber 100. The gas supply assembly 300 may include a gas supply source 302, a gas supply line 304, and a gas spray nozzle. The gas supply line 304 may connect the gas supply source 302 and the gas spray nozzle to each other. The gas supply line 304 may include a valve 306 configured to open and close the passage or adjust the amount of flow of a fluid flowing the passage.

The gas supplied from the gas supply assembly 300 may pass through the shower head assembly 400 and be supplied to the processing space of the chamber 100. According to the embodiment of the present disclosure, the shower head assembly 400 may be provided with a material including silicon. The shower head assembly 400 will be described below.

The plasma generating device 600 may generate plasma into the processing space of the chamber 100. The plasma may be generated in the upper area of the substrate support assembly 200 in the chamber 100. According to the embodiment of the present disclosure, the plasma generating device 600 may generate plasma to the processing space in the chamber 100 by using a capacitively coupled plasma (CCP) source.

However, the embodiment is not limited thereto. The plasma generating device 600 is possible to generate plasma to the processing space in the chamber 100 by using an inductively coupled plasma (ICP) source or a plasma source of a different method such as microwave, etc.

The plasma generating device 600 may include a high frequency power supply 602 and a matching device 604. The high frequency power supply 602 may supply high frequency power to an upper electrode or a lower electrode to generate a potential difference between the upper electrode and the lower electrode. Herein, the upper electrode may be the shower head assembly 400, and the lower electrode may be the substrate support assembly 200. The high frequency power supply 602 may be connected to the lower electrode, and the upper electrode may be earthed.

The controller 700 may generally control operation of the plasma processing apparatus 10 configured as described above. As an example, the controller 700 is a computer, and may include a central process unit (CPU), a random access memory (RAM), a read only memory (ROM), an auxiliary memory, etc. The CPU may be operated based on program or process conditions stored in the ROM or the auxiliary memory and may control the total operation of the plasma processing apparatus 10.

According to the embodiment of the present disclosure, the controller 700 may control supply of gas required for a process into the processing space of the chamber 100, and control the supplied gas to turn in plasma by the plasma generating device 600.

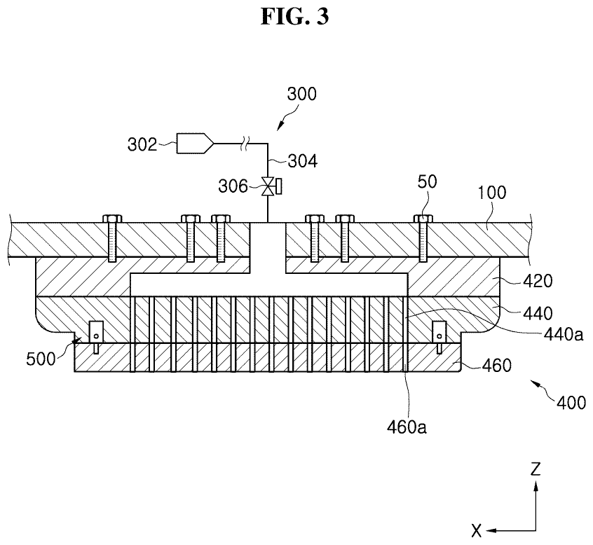

FIG. 3 is a sectional view illustrating a structure of the shower head assembly 400 according to the present disclosure. FIG. 3 is a view illustrating the shower head assembly 400 coupled to the chamber 100. Referring to FIG. 3, the shower head assembly 400 may include: an upper plate 420, a gas distribution plate 440, a shower plate 460, and a fastener 500.

The upper plate 420 may be installed in close contact with a lower surface of the chamber 100. According to the embodiment of the present disclosure, the upper plate 420 may be fastened to the chamber 100 by a fastening bolt 50. To supply the gas supplied from the gas supply assembly 300 to the gas distribution plate 440 and the shower plate 460, the upper plate 420 may be provided to have a predetermined space therein.

The gas distribution plate 440 may be arranged at a lower portion of the upper plate 420, and may be installed in close contact with the lower surface of the upper plate 420. At this point, although not shown in the drawing, the upper plate 420 and the upper plate 420 may be fastened to each other by a fastening bolt but is not limited thereto. The gas distribution plate 440 may include multiple through holes 440a to distribute gas.

The shower plate 460 may be arranged at a lower portion of the gas distribution plate 440. The shower plate 460 may have a form of a circular plate. The shower plate 460 may include multiple gas spraying holes 460a connected to the through holes 440a formed in the gas distribution plate 440. The gas distribution plate 440 and the shower plate 460 may be fastened to each other by the fastener 500.

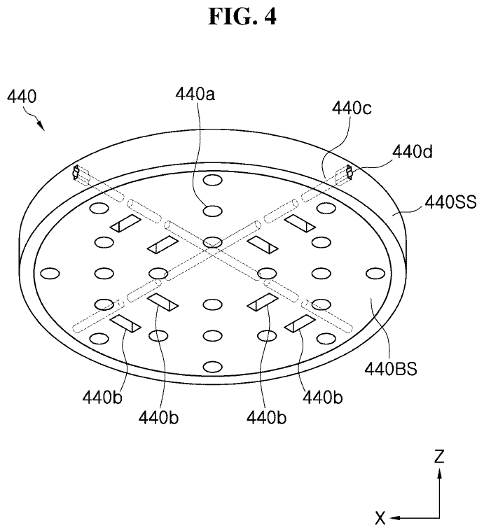

FIG. 4 is a view illustrating the gas distribution plate 440. Referring to FIG. 4, a lower surface 440BS of the gas distribution plate 440 may include the through holes 440a in which gas flows and a receiving space 440b to accommodate the fastener 500 therein. The receiving space 440b has a form of a groove or a trench depressed from the lower surface of the gas distribution plate 440. As shown in FIG. 4, the receiving space 440b may include multiple receiving spaces arranged in a linear direction from a center point of the gas distribution plate 440 toward an edge point thereof.

Meanwhile, a side surface 440SS of the gas distribution plate 440 includes a horizontal hole 440c passing through the internal portion of the gas distribution plate 440 in a horizontal direction. The horizontal hole 440c may pass from a portion of the side surface 440SS of the gas distribution plate 440 through the center portion to the opposite portion thereof. The horizontal hole 440c may include multiple horizontal holes 440c. The gas distribution plate 440 may include two horizontal holes 440c formed in perpendicular directions. Receiving grooves 440d having a vertically long pattern are formed at opposite ends of each horizontal hole 440c. As shown in FIG. 4, one horizontal hole 440c may be formed to pass through 3'Oclock point, the center point, and the 9'Oclock point of the gas distribution plate 440, and the other horizontal hole 440c may be formed to pass through the 12'Oclock point, the center point, and the 6'Oclock point. The receiving space 440b may include multiple receiving spaces arranged along the horizontal hole 440c. As shown in FIG. 4, as multiple fasteners 500 are coupled to the center and edge areas of the gas distribution plate 440, the center area and the edge area of the gas distribution plate 440 may be evenly provided in close contact with the shower plate 460.

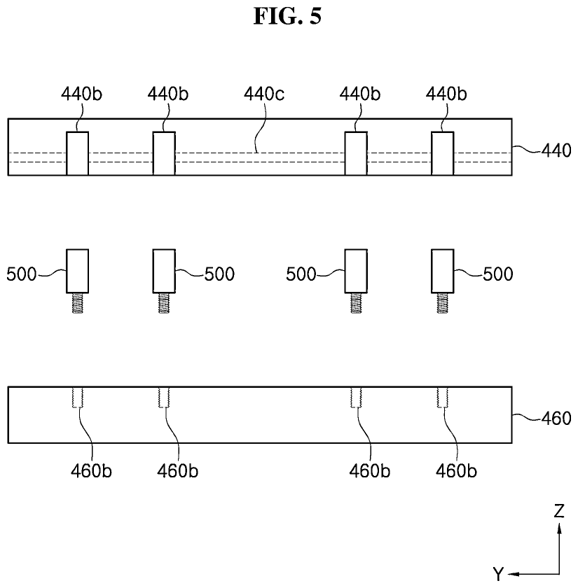

FIG. 5 is a view illustrating a coupling structure of the shower plate 460 and the gas distribution plate 440. Referring to FIG. 5, the fasteners 500 may be securely coupled to the fastening ports 460b formed in the shower plate 460. Each fastener 500 may be fixed to the shower plate 460 by a screw-structure fastening method. Thereafter, each fastener 500 is inserted into each receiving space 440b of the gas distribution plate 440.

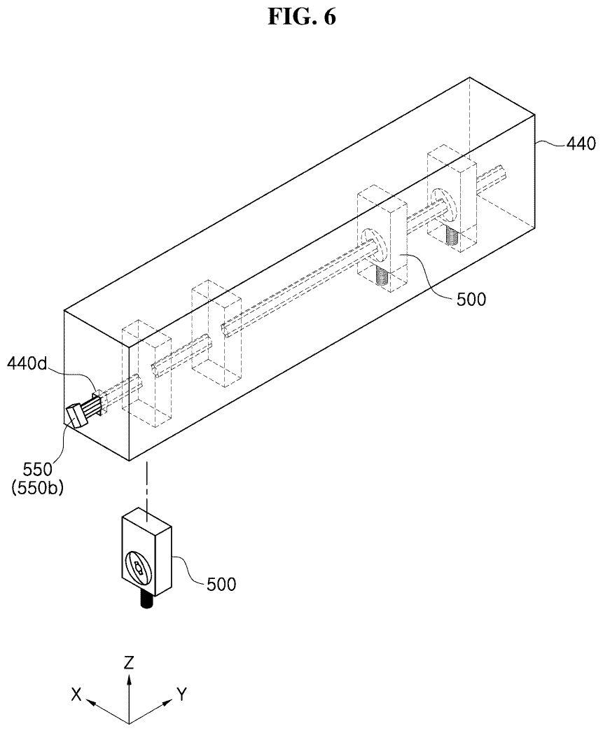

Each fastener 500 is inserted into each receiving space 440b formed in a vertical direction Z of the gas distribution plate 440, and a key rod 550 is inserted into each horizontal hole 440c as shown in FIG. 6, so the shower plate 460 and the gas distribution plate 440 are coupled to each other. Referring to FIG. 6, the key rod 550 inserted in the horizontal hole 440c of the gas distribution plate 440 passes through the multiple fasteners 500.

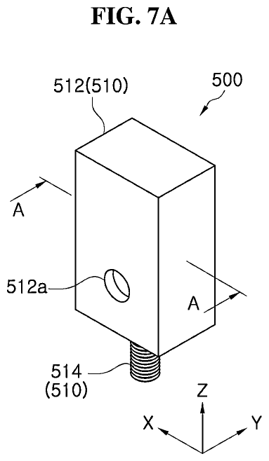

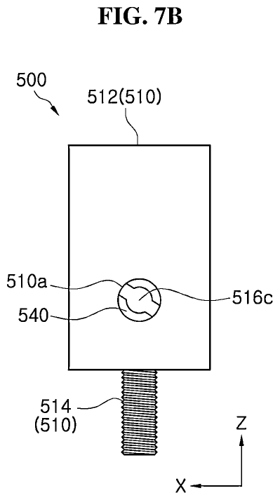

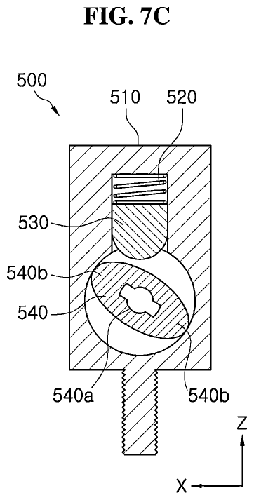

FIGS. 7A to 7C are views illustrating a structure of each fastener 500 of the shower head assembly 400. FIG. 7A is a perspective view of each fastener 500. FIG. 7B is a side view illustrating an exterior appearance of each fastener 500. FIG. 7C is an internal section of each fastener 500 taken along line A in FIG. 7A.

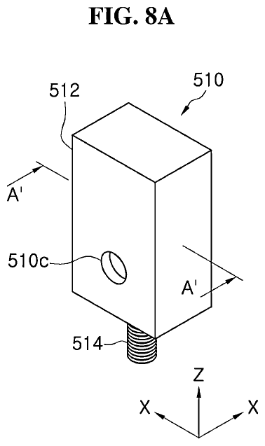

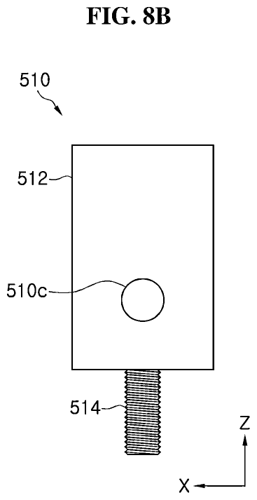

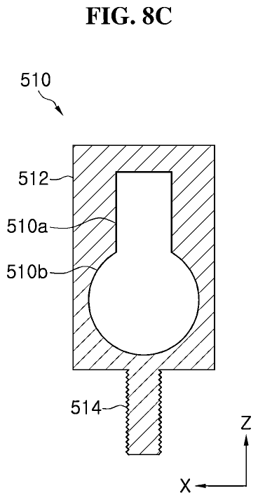

Each fastener 500 include a fixed block 510, a spring 520, a pressure block 530, and a rotation block 540. FIGS. 8A to 8C are views illustrating a structure of the fixed block 510. FIG. 8A is a perspective view of the fixed block 510. FIG. 8B is a side view illustrating an exterior appearance of the fixed block 510. FIG. 8C is an internal section of the fixed block 510 taken along line A′ in FIG. 8A. The fixed block 510 is securely fastened to the shower plate 460 and inserted into each receiving space 440b formed in the gas distribution plate 440. A first space 510a and a second space 510b are formed in the fixed block 510, and the first space 510a accommodates the spring 520 and the pressure block 530 and the second space 510b extends from a lower portion of the first space 510a and has a circular section. The fixed block 510 has a hexahedral shape with the first space 510a and the second space 510b formed therein, and the fixed block 510 includes a body part 512 inserted into each receiving space 440b of the gas distribution plate 440, and a screw part 514 extending from a lower portion of the body part 512 and coupled to each fastening port 460b formed in the shower plate 460. The fixed block 510 includes opening parts 510c on opposite outer walls of the second space 510b. Each of the opening parts 510c is a space through which the key rod 550 may pass and is formed to communicate with each horizontal hole 440c. Each opening part 510c may include a circular shape.

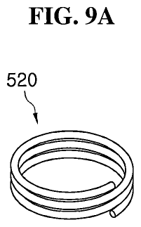

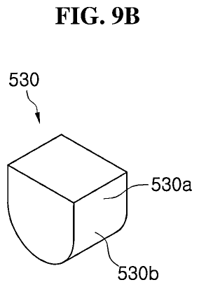

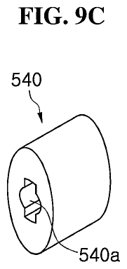

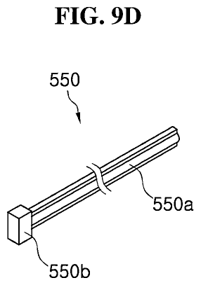

FIGS. 9A to 9D are views illustrating the spring 520, the pressure block 530, the rotation block 540, and the key rod 550. FIG. 9A is the spring 520, FIG. 9B illustrates the pressure block 530, FIG. 9C illustrates the rotation block 540, and FIG. 9D illustrates the key rod 550.

The spring 520 is inserted into the fixed block 510. The spring 520 may be a coil spring. The pressure block 530 includes an insertion part 530a in contact with the spring 520 and a pressure part 530b brought into contact with the rotation block 540 and having a semicircular section. More specifically, the pressure block 530 includes the insertion part 530a provided in contact with the spring 520 and having a rectangular section corresponding to the first space 510a, and the pressure part 530b brought into contact with the rotation block 540 and having a semicircular section. The pressure block 530 is configured such that the insertion part 530a having a rectangular section is pressed by the spring 520 and the pressure part 530b of the pressure block 530 presses the rotation block 540.

The rotation block 540 has a cylindrical shape with an oval section, and a pattern hole 540a having a specific pattern shape is formed in a center portion thereof. The rotation block 540 is located in the second space 510b of the fixed block 510 and is configured to be rotatable. When the rotation block 540 is pressed by the pressure block 530, the rotation block 540 has a posture in which a long axis end portion 540b lies in a horizontal direction X. On the contrary, when the rotation block 540 stands up in a vertical direction Z by the key rod 550, the long axis end portion 540b of the rotation block 540 presses the pressure part 530b of the pressure block 530.

The key rod 550 is inserted through each horizontal hole 440c of the gas distribution plate 440 and rotates the rotation block 540 while passing through a pattern hole 540a of the rotation block 540. The key rod 550 includes a rod part 550a and a nob part 550b. A sectional pattern of the rod part 550a of the key rod 550 is the same as a sectional pattern of the pattern hole 540a of the rotation block 540. The key rod 550 having a section corresponding to the pattern shape of the pattern hole 540a is configured to be inserted into the opening parts 510c and the pattern hole 540a to rotate the rotation block 540.

The key rod 550 may pass through the opening parts 510c and the pattern hole 540a to be inserted into the rotation block 540 of another fixed block 510, thereby rotating multiple rotation blocks 540 simultaneously.

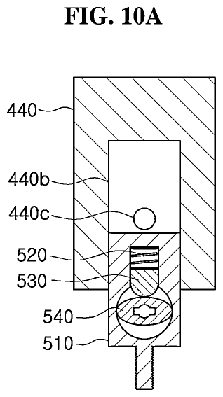

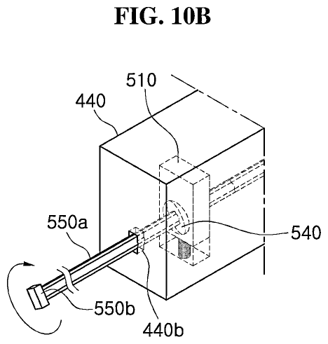

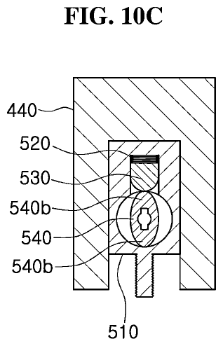

FIGS. 10A to 10C are views illustrating a process in which the gas distribution plate 440 and the shower plate 460 are coupled to each other by the fastener 500. FIG. 10A is a view without the key rod 550 inserted in the pattern hole 540a. FIG. 10B is a view illustrating the key rod 550 inserted into the pattern hole 540a and then rotating the rotation block 540. FIG. 10C is a view illustrating the rotation block 540 standing up in the vertical direction Z.

In FIG. 10A, each fastener 500 is inserted into each receiving space 440b of the gas distribution plate 440. At this point, in the fastener 500, the pressure block 530 pushes the rotation block 540 by an elastic force of the spring 520 and the rotation block 540 lies in the horizontal direction X. At this point, the gas distribution plate 440 and the shower plate 460 are not fixed and in a separated state.

In FIG. 10B, the rod part 550a of the key rod 550 is inserted through each horizontal hole 440c of the gas distribution plate 440, the opening parts 510c, and the pattern hole 540a. The rod part 550a of the key rod 550 may be simultaneously inserted into numerous fasteners 500. When the key rod 550 is rotated at 90 degrees clockwise or counterclockwise, the key rod 550 rotates the rotation block 540 at 90 degrees clockwise or counterclockwise.

In FIG. 10C, with rotation of the key rod 550, the rotation block 540 stands up in the vertical direction Z. In other words, the long axis end portion 540b of the rotation block 540 is located in the vertical direction Z, and the long axis end portion 540b is brought into contact with the pressure part 530b of the pressure block 530. Thereafter, the nob part 550b is inserted into each receiving groove 440d formed in the side surface 440SS of the gas distribution plate 440. Accordingly, the gas distribution plate 440 and the shower plate 460 are securely coupled to each other in close contact with each other.

On the contrary, when the key rod 550 is removed from the horizontal hole 440c with the rotation block 540 rotated and lying in the horizontal direction X by rotation of the key rod 550, as shown in FIG. 10A, the gas distribution plate 440 and the shower plate 460 are not coupled to each other. At this point, the shower plate 460 is separated from the gas distribution plate 440.

According to the present disclosure, with the key rod 550 rotated, the shower plate 460 and the gas distribution plate 440 may be fastened to each other or separated from each other.

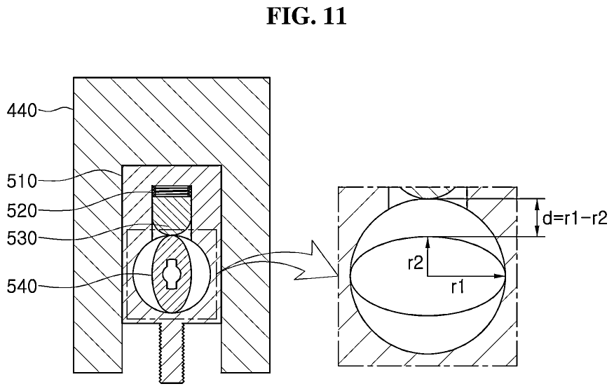

FIG. 11 is a view illustrating a process for determining the rotation block 540 and the spring 520. According to the present disclosure, in order for a function of each fastener 500 to be performed efficiently, a size of the rotation block 540 and an elastic force of the spring 520 may be determined.

In order for a function of each fastener 500 to be efficiently performed, when an external force by the key rod 550 is not applied, an elastic force sufficient to allow the rotation block 540 to lie in the horizontal direction X by the spring 520 is required, and when the rotation block 540 stands up in the vertical direction Z by rotation of the key rod 550, compressibility sufficient for the long axis end portion 540b of the rotation block 540 to maintain compression is required. An elastic force and compressibility of the spring 520 (a coil spring) may be determined according to a displacement length d corresponding to a difference between a long shaft radius r1 and a short shaft radius r2 of the rotation block 540.

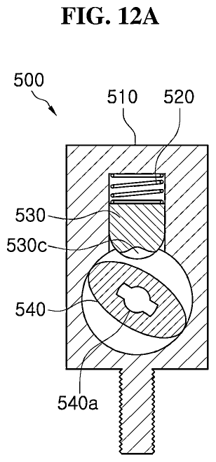

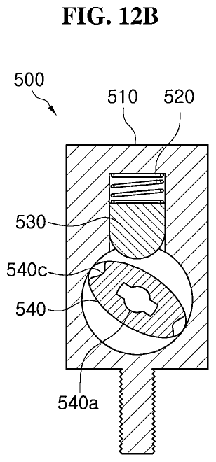

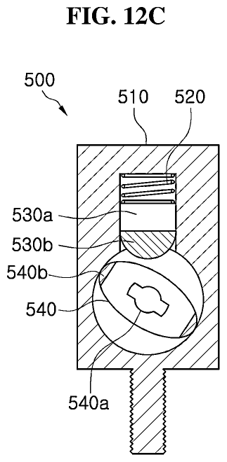

FIGS. 12A to 12C are views illustrating modifications of each fastener 500. FIG. 12A illustrates a modification in which a recessed portion 530c is formed at a portion of the pressure block 530 contacting with the rotation block 540. In FIG. 12A, the recessed portion 530c with an end of the pressure part 530b recessed inward is formed at the pressure block 530. When the rotation block 540 stands up in the vertical direction Z, the long axis end portion 540b of the rotation block 540 may be inserted into the recessed portion 530c. In this case, a standing posture of the rotation block 540 may remain stable.

Contrary to FIG. 12A, FIG. 12B illustrates a modification in which a recessed portion 540c is formed at a portion of the rotation block 540 contacting with the pressure block 530. In FIG. 12B, the recessed portion 540c with an end of the long axis end portion 540b recessed inward is formed at the rotation block 540. When the rotation block 540 stands up in the vertical direction Z, the pressure part 530b of the pressure block 530 may be inserted into the recessed portion 540c. In this case, a standing posture of the rotation block 540 may remain stable.

FIG. 12C illustrates a structure in which contact portions of the pressure block 530 and the rotation block 540 are made of a magnet material. The pressure part 530b of the pressure block 530 and the long axis end portion 540b of the rotation block 540 may be made of a magnet material having a tractive force for each other. When the rotation block 540 stands up in the vertical direction Z, the pressure part 530b of the pressure block 530 and the long shaft ends 540b of the rotation block 540 are held together and a standing posture of the rotation block 540 may remain stable.

Although the preferred embodiments of the present disclosure have been disclosed for illustrative purposes, those skilled in the art will appreciate that various modifications, additions and substitutions are possible, without departing from the scope and spirit of the invention as disclosed in the accompanying claims. Since the present disclosure may be embodied in other specific forms without changing the technical sprit or essential features, those skilled in the art to which the present disclosure belongs should understand that the embodiments described above are exemplary and not intended to limit the present disclosure.

Therefore, the spirit of the present disclosure will not be defined by the accompanying claims rather than by the detailed description, and those skilled in the art should understand that various modifications, additions and substitutions derived from the meaning and scope of the present disclosure and the equivalent concept thereof are included in the scope of the present disclosure.

What is claimed is:

1. A shower head assembly configured to spray a processing gas into a processing space of a chamber in which a substrate is processed in a plasma processing apparatus, the shower head assembly comprising:
an upper plate securely installed in an upper space of the chamber;
a gas distribution plate arranged at a lower portion of the upper plate and having multiple through holes;
a shower plate arranged at a lower portion of the gas distribution plate and having gas spraying holes connected to the through holes; and
a fastener configured to fasten the gas distribution plate and the shower plate, wherein the fastener comprises:
a fixed block securely fastened to the shower plate and inserted into a receiving space formed in the gas distribution plate;
a spring inserted into an internal space of the fixed block;
a pressure block installed at a lower portion of the spring;
a rotation block provided at a lower portion of the pressure block and having an oval section with a pattern hole formed therein; and
a key rod inserted into the pattern hole of the rotation block.

2. The shower head assembly of claim 1, wherein the fixed block comprises:
a body part having a first space and a second space formed in a circular shape below the first space, the body part being inserted into the receiving space of the gas distribution plate; and
a screw part formed to extend from a lower portion of the body part and coupled to a fastening port formed in the shower plate.

3. The shower head assembly of claim 1, wherein the spring is a coil spring.

4. The shower head assembly of claim 1, wherein the pressure block comprises:
an insertion part provided in contact with the spring; and
a pressure part brought into contact with the rotation block and having a semicircular section.

5. The shower head assembly of claim 1, wherein the fixed block has circular opening parts on opposite walls.

6. The shower head assembly of claim 5, wherein a pattern hole having a patterned shape is formed in the rotation block.

7. The shower head assembly of claim 6, wherein the key rod comprises:
a rod part having a section corresponding to the patterned shape; and
a nob part formed at an end of the rod part.

8. A shower head assembly configured to spray a processing gas into a processing space of a chamber in which a substrate is processed in a plasma processing apparatus, the shower head assembly comprising:
an upper plate securely installed in an upper space of the chamber;
a gas distribution plate arranged at a lower portion of the upper plate, having multiple through holes formed in a vertical direction, and having side holes formed in a horizontal direction passing through a central point;
a shower plate arranged at a lower portion of the gas distribution plate and having gas spraying holes connected to the through holes; and
a fastener configured to fasten the gas distribution plate and the shower plate, wherein the fastener comprises:
multiple fixed blocks securely fastened to the shower plate and inserted into multiple receiving spaces formed along the side holes;
a spring installed in an internal space of each fixed block;
a pressure block installed at a lower portion of the spring;
a rotation block provided at a lower portion of the pressure block and having an oval section with a pattern hole formed therein; and
a key rod inserted into the pattern hole of the rotation block.

9. The shower head assembly of claim 8, wherein each fixed block comprises:
a body part having a first space and a second space formed in a circular shape below the first space, the body part being inserted into the receiving space of the gas distribution plate; and
a screw part formed to extend from a lower portion of the body part and coupled to a fastening port formed in the shower plate.

10. The shower head assembly of claim 8, wherein the spring is a coil spring.

11. The shower head assembly of claim 8, wherein the pressure block comprises:
an insertion part provided in contact with the spring; and
a pressure part brought into contact with the rotation block and having a semicircular section.

12. The shower head assembly of claim 8, wherein each fixed block has circular opening parts on opposite walls.

13. The shower head assembly of claim 12, wherein a pattern hole having a patterned shape is formed in the rotation block.

14. The shower head assembly of claim 13, wherein the key rod comprises:
a rod part having a section corresponding to the patterned shape; and
a nob part formed at an end of the rod part.

15. The shower head assembly of claim 14, wherein the key rod passes through the opening parts and the pattern hole and is inserted into rotation blocks of the multiple fixed blocks simultaneously to rotate the multiple rotation blocks.

16. A plasma processing apparatus comprises:
a chamber providing a processing space for a substrate;
a substrate support assembly arranged in the processing space and configured to support the substrate;
a gas supply assembly configured to supply gas required for a process to the processing space; and
a shower head assembly configured to spray the supplied gas into the processing space,
wherein the shower head assembly comprises:
an upper plate securely installed in an upper space of the chamber;
a gas distribution plate arranged at a lower portion of the upper plate, having multiple through holes formed in a vertical direction, and having side holes formed in a horizontal direction passing through a central point;
a shower plate arranged at a lower portion of the gas distribution plate and having gas spraying holes connected to the through holes; and
a fastener configured to fasten the gas distribution plate and the shower plate,
wherein the fastener comprises:
a fixed block securely fastened to the shower plate, inserted into each of multiple receiving spaces formed in the gas distribution plate, and having a first space and a second space extending from a lower portion of the first space and having a circular section;
a spring installed at a ceiling of the first space;
a pressure block installed in the first space and at a lower portion of the spring;
a rotation block provided at a lower portion of the pressure block and having an oval section with a pattern hole formed therein; and
a key rod inserted into the pattern hole of the rotation block,
wherein circular opening parts are formed on walls of the second space of the fixed block,
a pattern hole having a patterned shape is formed in the rotation block,
the key rod is inserted into the opening parts and the pattern hole and rotates the rotation block, and
the key rod passes through the opening parts and the pattern hole and is inserted into rotation blocks of multiple fixed blocks simultaneously to rotate the multiple rotation blocks.

17. The plasma processing apparatus of claim 16, wherein the fixed block comprises:
a body part having a hexahedral shape with the first space and the second space formed therein and inserted into each receiving space of the gas distribution plate; and
a screw part formed to extend from a lower portion of the body part and coupled to a fastening port formed in the shower plate.

18. The plasma processing apparatus of claim 16, wherein the spring is a coil spring.

19. The plasma processing apparatus of claim 18, wherein an elastic force and compressibility of the coil spring are determined according to a displacement length corresponding to a difference between a long axis radius and a short axis radius of the rotation block.

20. The plasma processing apparatus of claim 16, wherein the pressure block comprises:
an insertion part provided in contact with the spring and having a quadrangle section corresponding to the first space; and
a pressure part brought into contact with the rotation block and having a semicircular section.
